(19) United States
(12) Patent Application Publication
(10) Pub. No.: US 2001/0052096 A1
(43) Pub. Date: Dec. 13, 2001

(54) Low power scan flipflop

(76) Inventor: Eduard Petrus Huijbregts, Eindhoven (NL)

Correspondence Address: Jack E. Haken, c/o PHILIPS CORPORATION, Intellectual Property Department, 580 White Plains Road, Tarrytown, NY, 10591, US

(21) Appl. No.: 09/747,105

(22) Filed: Dec. 21, 2000

(30) Foreign Application Priority Data
Dec. 24, 1999 (EP) 99204527.8

(51) Int. Cl. H03K 19/00; G01R 31/28

(52) U.S. Cl. 714/726

(57) ABSTRACT

The invention relates to a scan flipflop comprising a test input, a data input, a scan enable input, a Q output and an output QT formed by an output and an AND gate and inputs of the AND gate being connected to the Q output and to the scan enable input.

The invention relates to a scan flipflop comprising a test input, a data input, a scan enable input and a Q output.

Such a scan flipflop is known from U.S. Pat. No. 5,848,075. A scan flipflop shown in FIG. 5 thereof shows a test input to which is applied a scan in signal, a data input to which data are applied, a scan enable input to which a mode select signal is applied and a Q output. The data input and scan enable input both are directly connected to a selector circuit. The test input is connected to the selector circuit through a gating circuit comprising a transfer gate, two inverters connected in parallel and a capacitor. The transfer gate is controlled by the clock signal. Depending upon the value of the scan enable signal at the scan enable input either the data that are input at the data input or the signals at the test input are transferred to a d input of the flipflop. The presence of a transfer gate and two additional inverters and of a capacitor requires additional power to be supplied to the scan flipflop.

It is an object of the present invention to provide a scan flipflop having reduced power consumption, in integrated form does not require extra area and does not require extra hardware to slow down the scan chain to avoid data skew in scan mode.

These objects are achieved by a scan flipflop that according to the invention is characterised in that an output QT is formed by an output of an AND gate and in that inputs of the AND gate are connected to the Q output and to the scan enable input.

A scan chain comprising multiple scan flipflops according to the invention is characterised by multiple such scan flipflops according to the invention and by an output QT of a one of said multiple scan flipflops being connected to a test input of a next of said multiple scan flipflops.

Thereby it is achieved that not every transition on the Q ouput causes a transition of a test output, such as output QT, anymore. Such a transition dissipates energy due to charging and discharging of the capacitance associated with the scan chain interconnect and connected inputs. The output QT is only enabled (i.e. can switch) when the flipflop is in scan mode (i.e. when the scan enable signal TE at the scan enable input is high). In functional mode (i.e. when the scan enable signal TE at the scan enable input is low) the output QT will not follow the Q output and thus saves the energy that would otherwise be dissipated.

The invention will now be described in more detail with reference to the accompanying drawings in which:

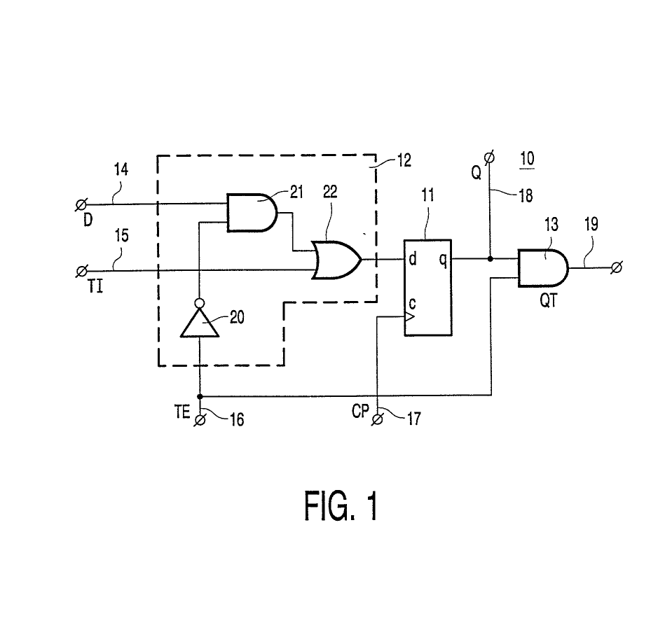

FIG. 1 shows a scan flipflop according to the invention;

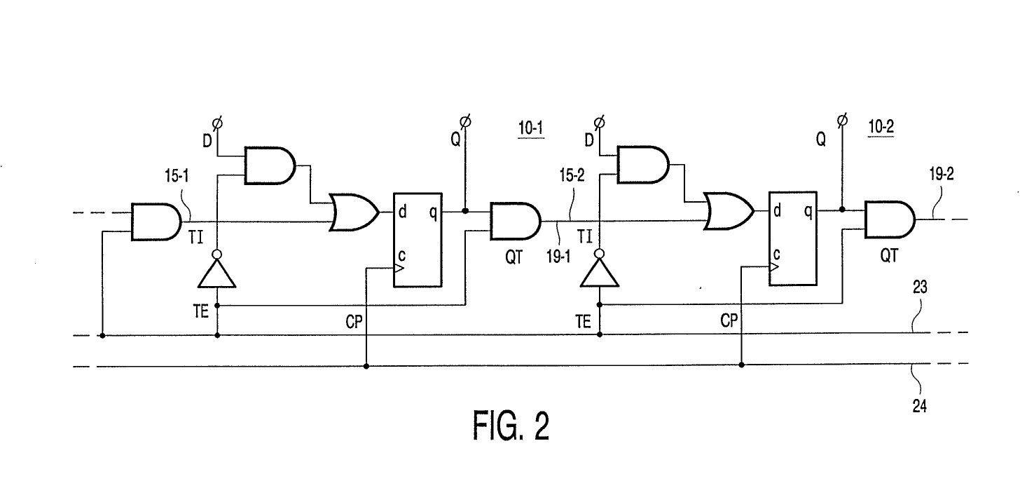

FIG. 2 shows a scan device comprising multiple scan flip-flops according to the invention.

Referring now to FIG. 1 a scan flipflop 10 comprises a flipflop 11, a selector circuit 12 and an AND gate 13. The flipflop 11 comprises an input d for data, an output q and a clock input c. Input of data to the scan flipflop takes place at data input 14, test input signals are supplied to the scan flipflop 10 through test input 15. A scan enable signal TE is supplied through a scan enable input 16. A clock signal CP is supplied through a clock input 17. An output signal Q is supplied at the Q output 18 and an output QT signal is supplied at the output QT 19.

The selector circuit 12 comprises an inverter 20, an AND gate 21 and an OR gate 22. Data input 14 is connected to a first input of AND gate 21. An output of AND gate 21 is connected to a first input of OR gate 22. A second input of OR gate 22 is connected to test input 15. An input of inverter 20 is connected to the scan enable input 16. An output of inverter 20 is connected to a second input of AND gate 21. An output of OR gate 22 is connected to the input d of flipflop 11. Output q of flipflop 11 is connected to the Q output 18 as well as to a first input of AND gate 13. A second input of AND gate 13 is connected to scan enable input 16.

The signal at scan enable input 16 determines whether data signals on data input 14 or test input signals at test input 15 are transferred by selector circuit 12 to input d of flipflop 11. In a functional mode, sometimes also called normal mode, of operation the signal TE at the scan enable input 16 is low. In that situation the selector circuit 12 operates to transfer data signals d at data input 14 to be transferred to input d of flipflop 11. Output signal Q at Q output 18 than switches states each time a rising signal at clock input c has appeared after a signal at data input 14 has switched states. Since the scan enable signal TE at scan enable input 16 is low the second input of AND gate 13 is low whereby the signal QT at output QT 19 remains low independent of the signal Q at the first input of AND gate 13. In other words the output QT will not follow the Q output and thus saves the energy that would otherwise be dissipated.

In case the scan enable signal TE at scan enable input 16 is high scan flipflop 10 operates in scan mode and may operate as part of a scan chain comprising multiple scan flipflops. In case the scan enable signal TE at scan enable input 16 is high selector circuit 12 operates to block any data signals at data input 14 and to transfer any test input signals at test input 15 to input d of flipflop 11. Again as described herein before a Q signal at Q output 18 is switched by a test input signal TE at test input 15. However since now the scan enable signal TE at scan enable input 16 is high the second input of AND gate 13 is high and output QT 19 follows Q output 18.

Referring now to FIG. 2 there are shown two scan flipflops 10-1 and 10-2 which are connected with their scan enable inputs to a scan enable signal line 23 and with their clock inputs c to a clock line 24. Output QT 19-1 of scan flipflop 10-1 is connected to test input 15-2 of scan flipflop 10-2. In the same way test input 15-1 of scan flipflop 10-1 is connected to an output QT of a previous scan flipflop and output QT 19-2 of scan flipflop 10-2 is connected to a test input of a next scan flipflop.

When a scan enable signal at scan enable line 23 is low all outputs QT 19, and thereby all test inputs 15 of the scan flipflops 10 in the scan chain shown in FIG. 2 will be low. All outputs QT 19 will not follow their corresponding Q outputs and thus save the energy that would otherwise be dissipated.

When the scan enable signal TE at scan enable line 23 is high the output signals QT at the outputs QT 19 will follow the Q signals at the corresponding Q outputs, which QT output signals form test input signals at test inputs 15 of next scan flipflops.

In prior art devices extra measures have to be taken to prevent data skew (sometimes also called clock skew). Data skew or clock skew is a result thereof that in scan mode signals have to travel through a fewer numbers of gates. The introduction of the AND gate 13 introduces an extra delay in the transfer of the test input signals through the scan device. Thereby data skew or clock skew may be prevented to a large degree or completely. Complete prevention can be achieved by sizing of the output QT buffer transistors. Thereby it is achieved that no extra hardware is required to slow down the scan device to avoid data skew in scan mode.

1. Scan flipflop comprising a test input (15), a data input (14), a scan enable input (16) and a Q output (18), characterised in that an output QT (19) is formed by an output of an AND gate (13) and in that inputs of the AND gate (13) are connected to the Q output (18) and to the scan enable input (16).

2. Scan chain comprising multiple scan flipflops (10-1, 10-2) operable in a scan mode and at least one other mode, characterised by multiple scan flipflops (10-1, 10-2) according to claim 1 and by an output QT (19-1) of a one (10-1) of said multiple scan flipflops (10-1, 10-2) being connected to a test input (15-2) of a next (10-2) of said multiple scan flipflops.

3. Scan chain according to claim 2, characterised by output QT buffer transistors sized to slow down the scan chain for compensation of data skew during scan mode.

4. Scan chain according to claim 2 or 3, characterised by output QT buffer transistors sized to slow down the scan chain for complete compensation of data skew during scan mode.
